(19) United States
(12) Patent Application Publication
(10) Pub. No.: US 2016/0204012 A1
(43) Pub. Date: Jul. 14, 2016

(54) SUBSTRATE CONTAINMENT WITH ENHANCED SOLID GETTER

(71) Applicant: ENTEGRIS, INC., Billerica, MA (US)

(72) Inventor: Gregory BORES, Prior Lake, MN (US)

(21) Appl. No.: 14/917,234

(22) PCT Filed: Sep. 5, 2014
(86) PCT No.: PCT/US2014/054399

§ 371 Date: Mar. 7, 2016

Related U.S. Application Data
(60) Provisional application No. 61/874,697, filed on Sep. 6, 2013.

(51) Int. Cl. H01L 21/673

(52) U.S. Cl. CPC H01L 21/67393

(57) ABSTRACT

A containment for one or more substrates has an enclosure that defines a contained volumetric area and included therein is a block or plate getter unit that has an enhanced performance provided by increased surface area formed on the plate or block by a series of grooves or other repeating surface structure pattern. Such patterning provides increased surface area on the block or plate and thus increased exposure of active elements to the contained volumetric region. In an embodiment, structure on one side of the block or plate has mirror image surface or a complementary surface on the opposing side. With such a structure, rigidity of the block or plate is preserved, weight is minimized, and exposed surface area is maximized. The enclosure may have specific pockets or may utilize a conventional substrate slot for the block or plate getter. The plate or block getter may be configured to fit within a conventional slot or a dedicated pocket in a wafer container or other substrate container.

### RELATED APPLICATION

This application claims the benefit of U.S. Provisional Patent Application No. 61/874,697, filed Sep. 6, 2013, the disclosure of which is hereby incorporated by reference herein in its entirety.

### FIELD OF THE INVENTION

This invention relates to moisture and contaminant control associated with substrate containers such as semiconductor wafer containers and reticle pods.

### BACKGROUND OF THE INVENTION

Substrates such as wafers and reticles utilized in semiconductor processing are highly vulnerable to contaminants, including moisture, volatile organic components (VOC's), and particles. The presence of moisture can be a very significant contributor to development of haze growth on both reticles and wafers. A very effective means of controlling contaminants, including moisture, is by way of continual or periodic purging of the space where substrates are stored or secured. Typically this is in closed polymer containers such as manufactured by Entegris, Inc., the owner of this application. During shipment of substrates, it is not practical to utilize purging and other means such as getters may be utilized to keep moisture and VOC's to acceptable levels. Such getters may be in the form of granular desiccants or rigid plates, see for example U.S. Pat. No. 5,346,518, incorporated by reference herein, illustrating rigid plates in a wafer container. Such rigid absorbent plates or discs are also known in containers for shipping memory discs, see U.S. Pat. No. 4,721,207, incorporated herein by reference.

Such desiccants, particularly suited to absorbing VOC's may also be termed molecular sieves and are available in molded plates or blocks. See WO 2012116041 and U.S. Pat. No. 5,911,937 incorporated herein by reference. Conventional plates formed of such molecular sieve material are planar on opposite sides and have a periphery.

Due to the severe detrimental effect of moisture, VOC's, and AMCs on semiconductor production, any incremental improvement in the control of such is important and of value.

### SUMMARY OF THE INVENTION

A containment for one of more substrates has an enclosure that defines a contained volumetric area and included therein is a block or plate getter unit that has an enhanced performance provided by increased surface area formed on the plate or block by a series of grooves or other repeating surface structure pattern. Such patterning provides increased surface area on the block or plate and thus increased exposure of active elements to the contained volumetric area. In an embodiment, structure on one side of the block or plate has mirror image surface or a complementary surface on the opposing side. With such a structure, rigidity of the block or plate is preserved, weight is minimized, and exposed surface area is maximized. The enclosure may have specific pockets or may utilize a conventional substrate slot for the block or plate getter. The plate or block getter may be configured to fit within a conventional slot or a dedicated pocket in a wafer container or other substrate container.

In embodiments of the invention, a plate of getter material with enhanced exposed surface area is inserted into a wafer slot of a wafer shipping container during shipment of wafers in the container, or during shipment of a container void of wafers to minimize moisture in the containment provided by the container. This minimization may be both in the atmosphere therein and also effective for minimizing moisture absorbed by the walls of the container. In embodiments the plate is corrugated.

In an embodiment of the invention a reticle pod with a particular shaped interior cavity may receive and hold a plate of a polymer with a molecular sieve or absorbent material and an enhanced surface area in a polymer matrix, the plate having a shape corresponding to the cavity and being retained therein. In embodiments the plate is corrugated with corresponding repeating patterns on both sides of the plate.

In embodiments of the invention, a getter material formed of a polymer with a molecular sieve material therein is pelletized and injection molded or extruded to form a getter plate or block with repeating surface structure on two sides of the plate or block. In embodiments, the plate or block has a first greater dimension, a second greater dimension, and a third minor dimension corresponding to a length, width, and thickness, and wherein one of the first and second greater dimensions are at least 10 times the lesser dimension. In embodiments, the plate or block has a first greater dimension, a second greater dimension, and a third minor dimension corresponding to a length, width, and thickness, and wherein first and second greater dimensions are at least 15 times the lesser dimension. In embodiments of the invention grooves on greater first side surface and a greater second side surface have a depth of at least 40% of the thickness of the item between the first side surface and second side surface.

In embodiments, the getter has a length l, a width w, and thickness t, and with the lattice structure, the surface area is at least 50% greater than 2(l×w)+2(l×t)+2(w×t). In embodiments, at least 100% greater than 2(l×w)+2(l×t)+2(w×t). In other words, at least 200% of 2(l×w)+2(l×t)+2(w×t). In an embodiment, the getter provides twice as much exposed surface area as a rectangular cuboid of the same dimensions.

In embodiments, the getter is made from a preform that is generally a rectangular cuboid with a length l, a width w, and thickness t, and an exterior surface area of 2(l×w)+2(l×t)+2(w×t) or slightly less due to rounded corners. In embodiments the surface area of the preform is within 20% of 2(l×w)+2(l×t)+2(w×t). The getter then has structure formed thereon to increase the exterior surface area at least 50% of the getter preform surface area. In embodiments, the structure formed thereon increases the surface area at least 80%. In embodiments, the structure formed thereon increases the surface area at least 100%(or doubling). In embodiments, the structure formed thereon increases the surface area at least 150%. In embodiments, the structure formed thereon increases the surface area at least 200% of the original surface area. The added structure may be formed by machining or otherwise removing material from the preform.

In embodiments, a repeating recessed structure may be formed by molding sheets of polymeric getter material into the final form by vacuum molding or heated presses. Also, extrusions of structured sheet material can provide greatly enhanced surface area over plates of the same overall dimensions.

A feature and advantage of embodiments of the invention is the getters with increased surface area are still rigid and will not slough particles as compared to conventional getters such as granular desiccants, layered getters,

A feature and advantage of embodiments of the invention is the getters with increased surface area is they may be easily handled and secured into pockets or slots of substrate holders and provide enhanced performance over conventional getters with non grooved or highly randomized surfaces.

In an embodiment, a latticed plate is provided for a substrate carrier. In embodiments of the invention, a plurality of latticed plates may be stacked to provide extended or increased take-up capabilities.

A feature and advantage of embodiments of the invention is the getters highly structured sides providing increased surface area. The structure may be repeating grooves, lattice structure, apertures, or other structure.

A feature and advantage of the invention is providing protection in substrate containers from airborne molecular contaminants (AMC's), volatile organic contaminants (VOC's), and particles, whilst providing a convenient getter with structural rigidity and improved performance.

A feature and advantage of the invention is the improved performance in the semiconductor processing context is provided using available materials with minimal additional costs.

A feature and advantage of embodiments of the invention is that getters are provided for substrate containers are more effective due to higher ratios of surface area to getter volumetric area.

A feature and advantage of embodiments of the invention is that getters are formed by combining polymers with channeling agents and absorbent material such as desiccants. The effectiveness, capacity, and useful life may be controlled by adjusting various parameters such as the surface area to volumetric area; relative amounts and selection of channeling agent, selection and quantity of absorbent material.

### DESCRIPTION OF THE DRAWINGS

FIG. 1 is a perspective view of a front opening wafer carrier with a getter plate with parallel grooves on a disk in a wafer slot.

FIG. 2 is a perspective view of a dual containment substrate container with an inner pod and an outer pod and a getter plate with grooves positioned in the containment provided by the outer pod.

FIG. 3 is a perspective view of a clam shell mask container with a getter with grooves positioned therein as illustrated by the phantom lines.

FIG. 4 is a side elevational cross sectional view of the mask container of FIG. 3. e with grooves on opposing sides.

FIG. 5A is a prior art perspective view of a getter plate that may be used as a preform in accord with the embodiments herein.

FIG. 5B is a perspective view of a getter plate with grooves on opposing sides that may be formed from the preform of FIG. 5A.

FIG. 6 is a top plan view of the getter plate of FIG. 5, the bottom view being the same view.

FIG. 7 is a side view of the getter plate of FIG. 6.

FIG. 8 is a perspective view of a getter plate with grooves on opposing sides.

FIG. 9 is a side view of the getter plate with grooves of FIG. 8.

FIG. 10 is an end view of the getter plate of FIG. 8, the opposite end view being the same.

FIG. 11 is a profile of an alternate groove structure.

FIG. 12 is a profile of an alternate groove structure.

FIG. 13 is a profile of an alternate groove structure.

FIG. 14 is a perspective view of a getter plate with bi-directional corrugation slots on opposing sides.

FIG. 15 is a top plan view of the getter plate of FIG. 14, the bottom view being the same view.

FIG. 16 is a side view of the getter plate of FIG. 14. The view from each side view being the same.

FIG. 17 is a perspective view of a getter plate holes extending to opposing sides.

FIG. 18 is a top plan view of the getter plate of FIG. 17, the bottom view being the same view.

FIG. 19 is a side view of the getter plate of FIG. 17. The view from the opposite side view being the same.

FIG. 20 is an end view of the getter plate of FIG. 17. The view from the opposite end being the same.

FIG. 21 is a perspective view of a getter plate with grooves on opposing sides.

FIG. 22 is a perspective view of a getter plate with bi-directional corrugation slots on opposing sides.

FIG. 23 is a perspective view of a getter plate holes extending to opposing sides.

FIG. 24A is a prior art perspective view ea getter plate that may be used as a preform in accord with the embodiments herein.

FIG. 24B is a perspective view of a getter plate with bi-directional corrugation slots on opposing sides that may be formed from the preform of FIG. 24A.

FIG. 25A is a view of prior art polymeric getter material in sheet form.

FIG. 25B is a view of a surface enhanced getter suitable for use with the inventions herein and that may be formed form the sheet material of FIG. 25A or that may be extruded.

FIG. 26 is a view of a getter plate according to embodiments of the invention herein having a lattice structure on two opposite major sides.

FIG. 27 is a view of a getter plate according to embodiments of the invention herein having apertures extending through a circular form.

### DETAILED DESCRIPTION

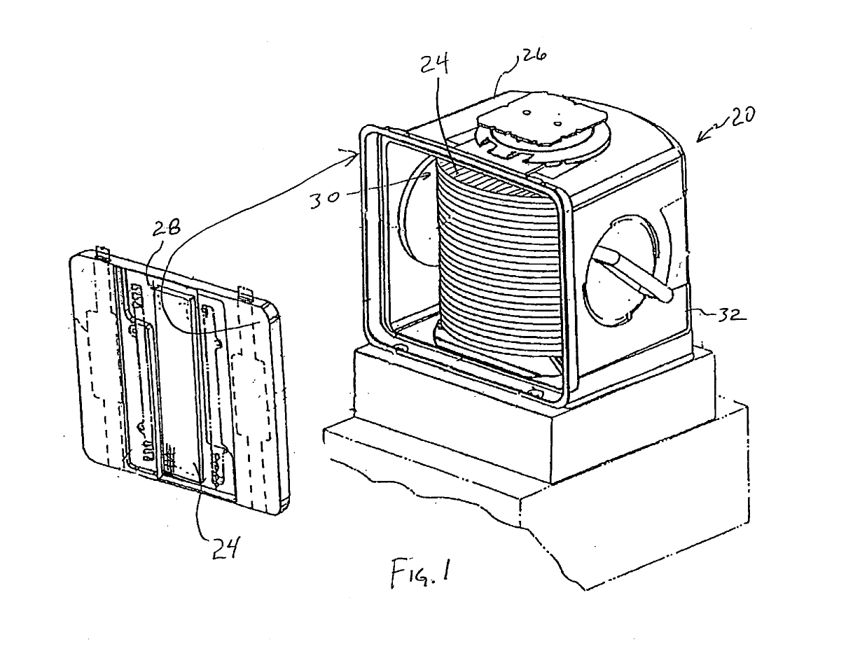

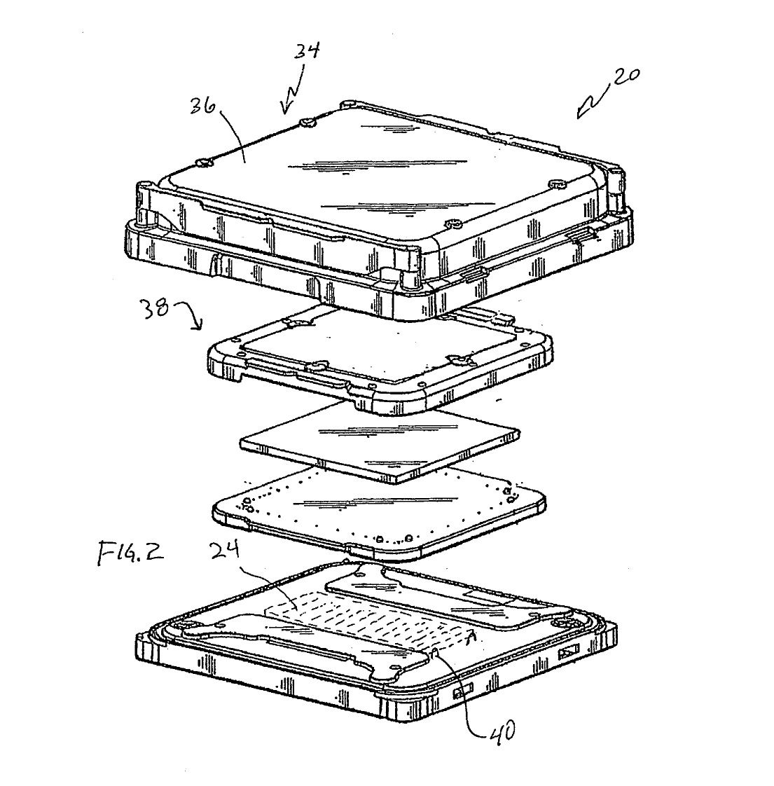

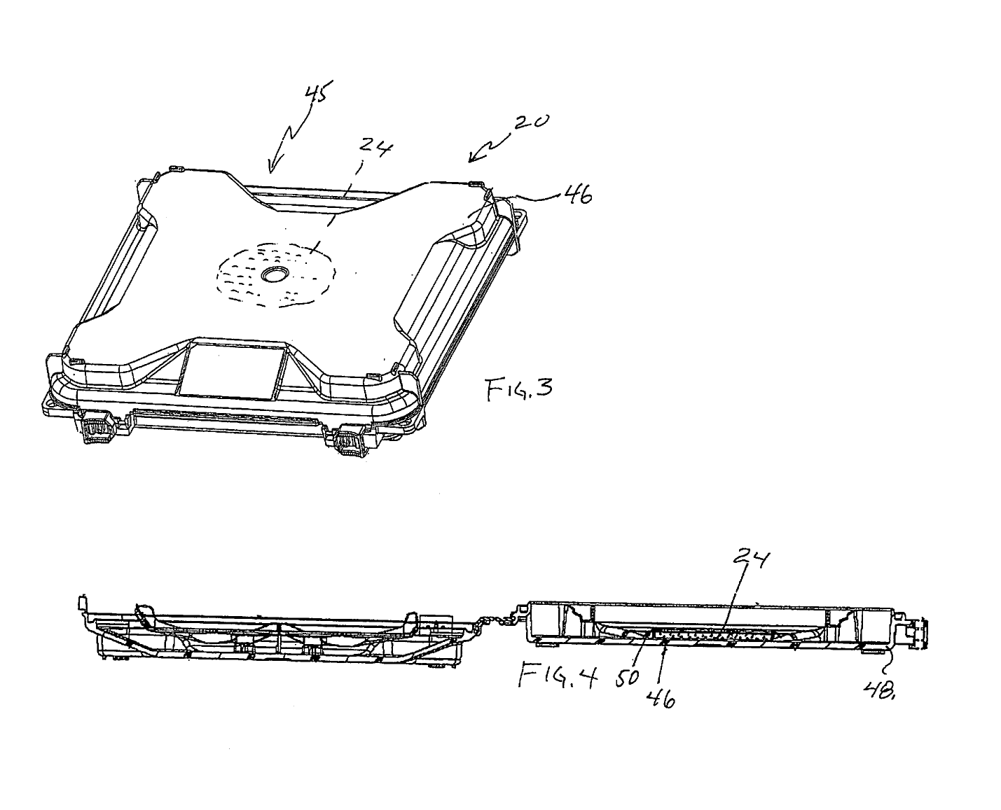

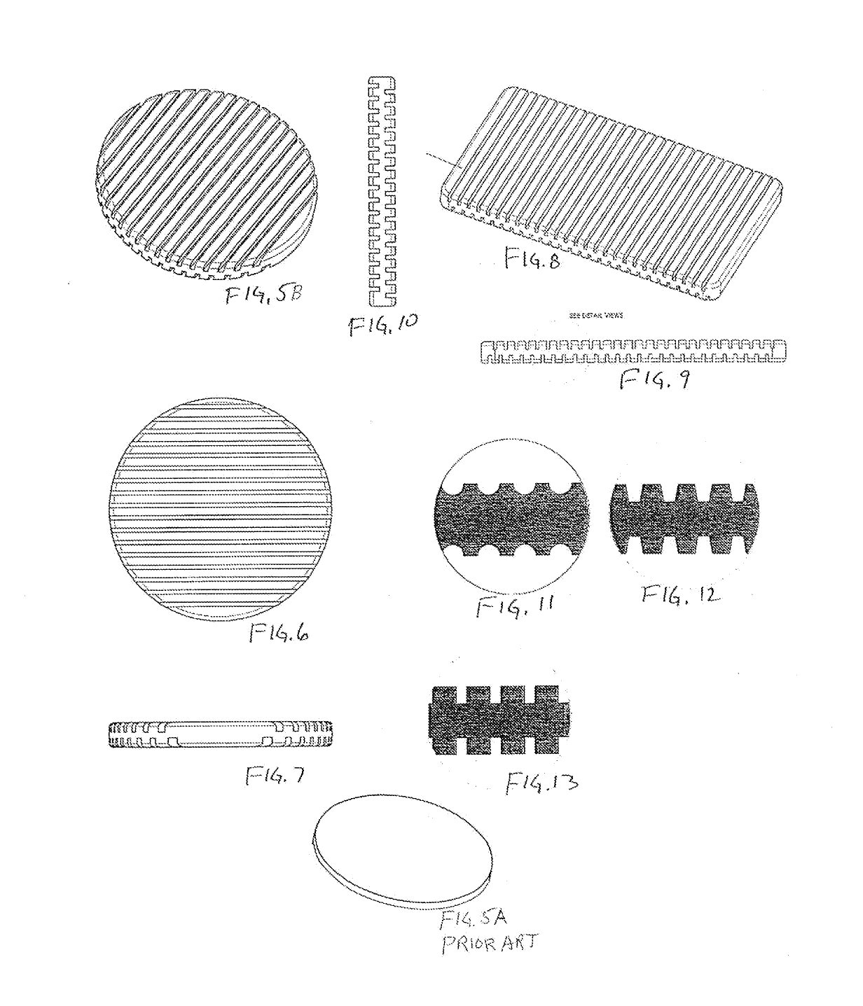

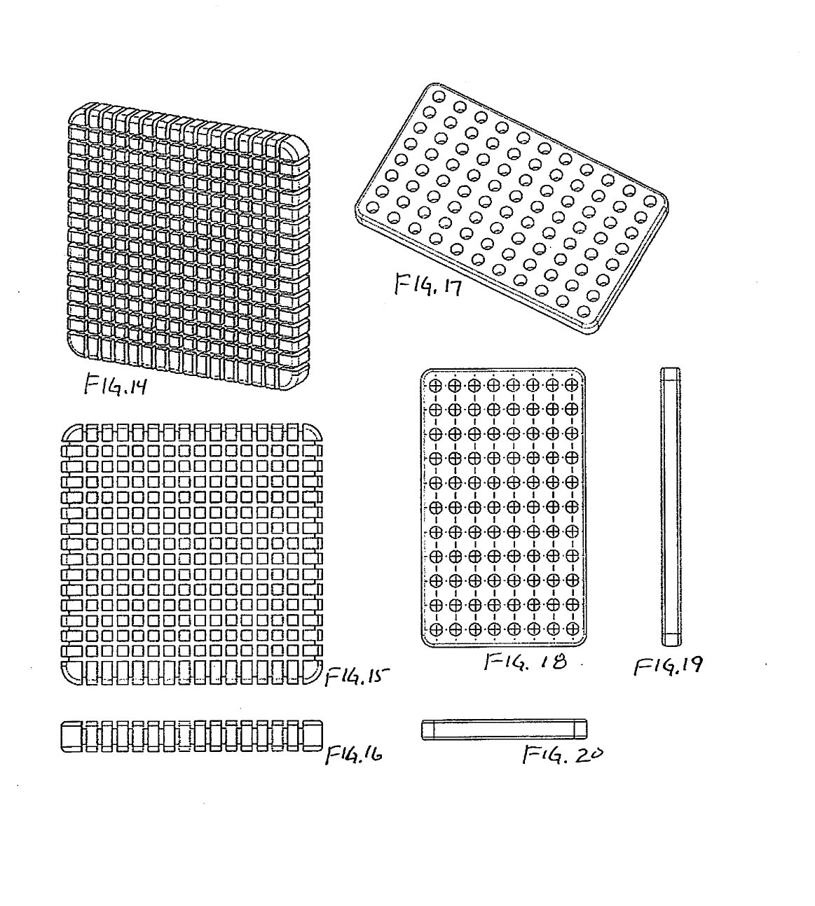

Referring to FIGS. 1-4, various substrate containers 20 are illustrated with an added getter 24. Substrates, when used herein may be wafers that will be or that are being processed into integrated circuits, or solar panels, or flat panels, or other semiconductor devices; substrates also includes reticles used in lithograph, disks used in memory disks, such as hard drives. The getters having the enhanced surface area as described below. FIG. 1 is a front opening wafer container 26, commonly known as a FOUP (front opening unified pod) having a getter 24 positioned in the central vertical recess 28 of the front door and in a slot 30 in the container portion 32. In different embodiments, additional getters with surface area enhancement may be positioned in the FOUP, in the wafer slots or in other areas.

FIG. 2 illustrates a dual containment reticle pod 34 with an outer pod 36 and an inner pod 38; such pods are used in extreme ultraviolet (EUV) photolithography and are described in U.S. Pat. No. 8,231,005, incorporated by reference herein. A getter 24 with latticed or corrugated configuration may be put in the outer pod containment to minimize the contaminants and is particularly suitable in this configuration where there is minimal or no space for getters in the inner pod. Features 40 may secure the getter to the lower door 42 of the outer pod. In embodiments, the getter or an additional getter may be secured in the inner pod as well.

FIG. 3 illustrates a mask container 45 with a getter 24 with surface area enhancement secured to the top 46 of the cover 48. Catches 50 or other features may secure the getter in the cover. Such features may provide a gap between the getter and the wall to allow the structure of the getter surface facing the wall to be operative.

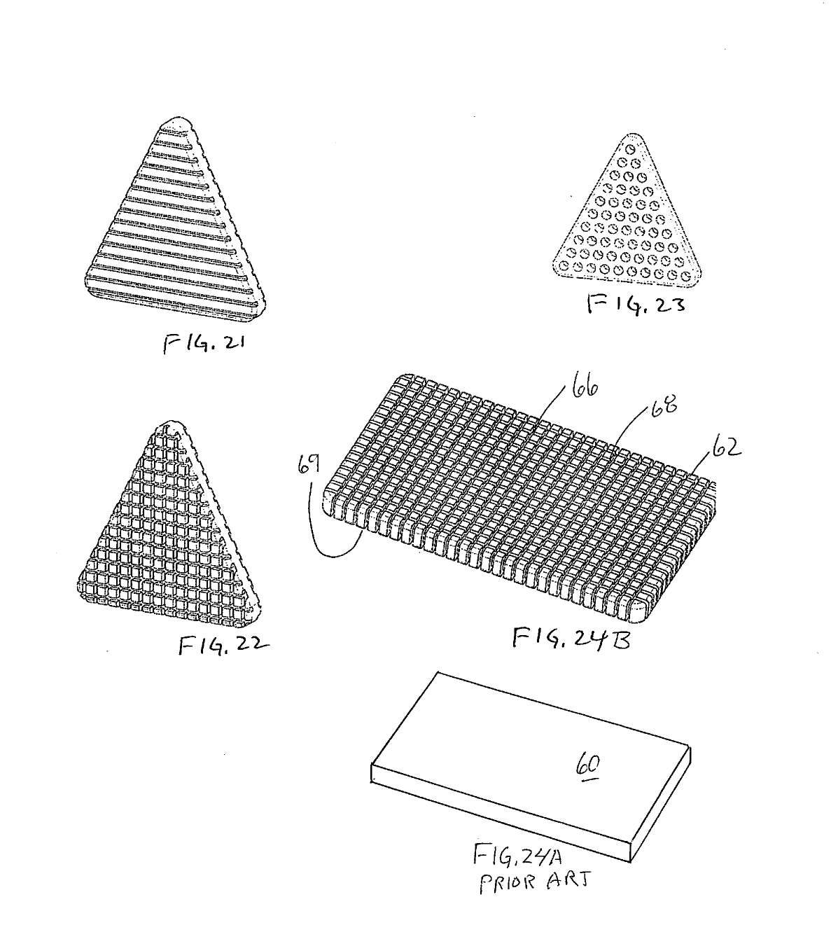

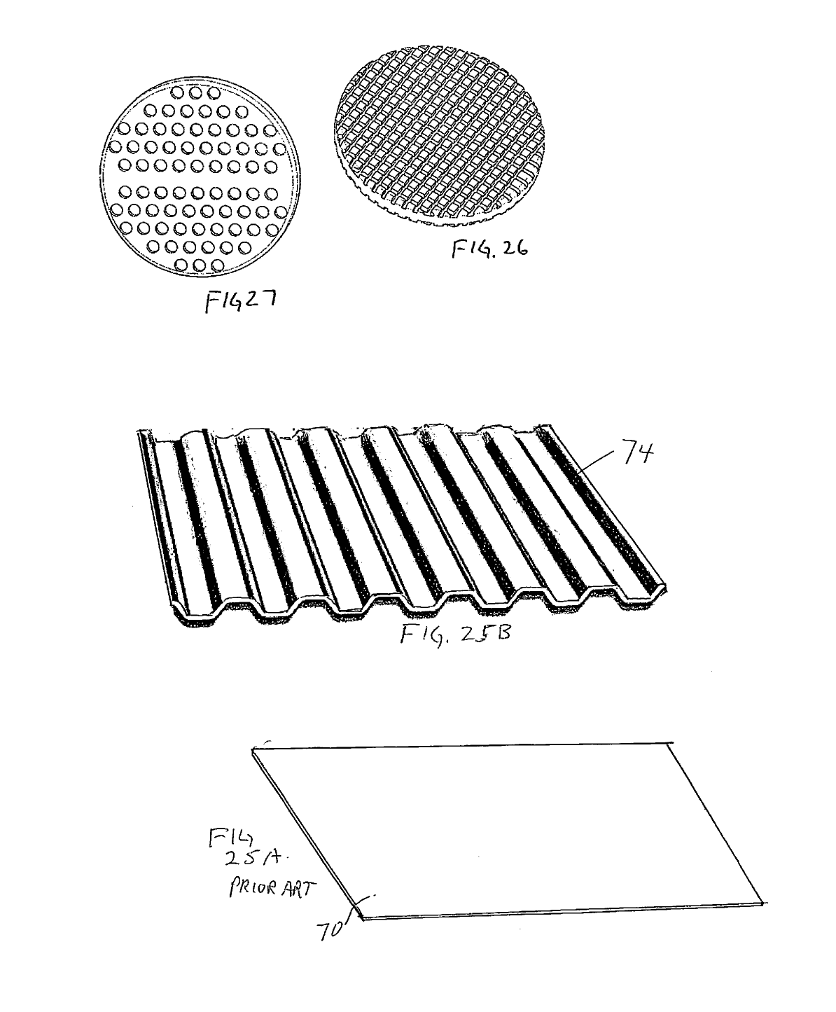

FIGS. 5-26 illustrate various configurations of getters in accord with the invention herein. Generally a plate or block shaped form has grooves formed by molding or machining or extruding that greatly increase the surface area of the form. The form may be a molded or machined or extruded polymer piece with a polymer matrix holding desiccant or molecular sieve material. Molecular sieve materials such as zeolite are suitable. Solid block forms, without enhanced surface area configurations, are available from, for example, AGM Container Controls, Tucson, Ariz. 85717. See also U.S. Pat. No. 7,531,275 illustrating getter and sieve material in the context of photomask container or reticle pod and various molecular sieve materials. Said patent is incorporated herein by reference. Also molecular sieve materials and polymer matrices are disclosed in US20080295691; US2009152763; PCT/US2008/061414(WO2008150586); US20060105158; U.S. Pat. No. 5,911,937; which are all incorporated herein by reference.

In embodiments, the getter may comprise a polymer base, a channeling agent and a desiccant. In these embodiments the polymer is preferably a thermoplastic polymer. The channeling agent is a compound which is not soluble in the polymer and the desiccant may be either a molecular sieve or silica gel. See, for example, U.S. Pat. No. 5,911,937, hereby incorporated in its entirety. Thermoplastic polymers are advantageous in that they can be molten and resolidify upon cooling. Thermoplastics are therefore excellent for use in injection or blow molding while when in their molten state other polymers may be added thereby making co-polymers, increasing the versatility of the polymer. Other compounds that can be mixed into the molten polymer including desiccants and channeling agents. In embodiments, the channeling agent is ethylene-vinyl alcohol (EVOH) and polyvinyl alcohol (PVOH).

Thermoplastic polymers include acrylics such as poly(methyl methacrylate) (PMMA); polyamides, such as nylon; polybenzimidazole (PBI); polyethylene, including ultra-high molecular weight polyethylenes (UHMWPE), high-density polyethylene (HDPE), and low-density polyethylene; polypropylene (PP); polystyrene; polyvinyl chloride (PVC); and polytetrafluoroethylene (PTFE). Each of these polymers has different characteristics with regard to its glass transition temperature, crystallinity and solubility. However, because thermoplastics and be readily mixed into copolymers, these characteristics can be tuned for use greatly increasing their utility and applications for use. Such copolymerization can be used to tune the plastic to meet specific needs such as hardness, elasticity, inertness, solubility etc. For example, fluorine is often added to thermoplastic polymers which leads to increasing chemical stability, melting point, reducing flammability, solubility due to the fluorine atoms unique characteristics. Non-limiting examples of fluorinated copolymers include Fluorinated ethylene propylene or FEP, perfluoroalkoxy polymer resin (PFA) and Ethylene ChloroTriFluoroEthylene (ECTFE).

Examples of such commercially used copolymers include acrylonitrile butadiene styrene (ABS), ABS combines the strength and rigidity of acrylonitrile and styrene polymers with the toughness of polybutadiene rubber. While the cost of producing ABS is roughly twice the cost of producing polystyrene, it is considered superior for its hardness, gloss, toughness, and electrical insulation properties. Styrene-butadiene rubber (SBR), SBRs are known for their abrasion resistance and aging stability. Nitrile rubber, a copolymer of acrylonitrile (ACN) and butadiene; styrene acrylonitrile resin a copolymer of styrene and acrylonitrile; ethylene vinyl acetate (also known as EVA) is the copolymer of ethylene and vinyl acetate and fluorinated copolymers which tend to be low friction and nonreactive and also easily moldable.

Examples of desiccants include anhydrous salts that form crystals that contain water, reactive compounds that undergoes chemical reaction with water to form new compounds, the third are physical absorbers which have a plurality of microcapillaries therein and so wick moisture out of the environment, Examples of such absorbers include molecular sieves, silica gels, clays and starches.

Channeling agents are used to form passages through the polymer that are communicable with the desiccant. Examples of such channeling agents include, but are not limited to ethylene-vinyl alcohol (EVOH) and polyvinyl alcohol (PVOH). In some embodiments, the channeling agent and the desiccant are mixed and the mixture is added to the molten polymer. Upon cooling the channeling agent and the desiccant separate into distinct domains throughout the mixture thereby creating channels throughout the hardened polymer some of those channels running to the surface of the polymer and thereby creating a matrix of channels throughout the polymer. These channels then expose the desiccant particles trapped within the polymer matrix and allow the desiccant to wick moisture from the outer compartment through the polymer base. In other embodiments, the desiccant and the channeling agent are mixed directly into the molten polymer without pre-mixing.

Because polymers as a whole tend to be non-polar and the channeling agent is tends to be polar (one reason the polymer and the channeling agent separate) it is often helpful to use a desiccant that is also polar. Thus, as the mixture cools and the channeling agent separates from the polymer the desiccant will tend to separate with the polar channeling agent and not the polymer resulting in channels that lead directly to the desiccant instead of a desiccant that is entrapped within the polymer.

In embodiments, activated carbon may be the absorbing material, particularly for VOC's. Such have been used with absorbent plates in substrate containers, see U.S. Pat. No. 5,346,519. The activated carbon may also be utilized as the desiccants above in a polymer matrix with a channeling agent. Such may be combined with other specific desiccants. And more than one channeling agent may be utilized.

One way of manufacturing the getters of FIGS. 5-26 is by machining such solid block polymer forms. Alternatively, injection molding or extruding can also provide the configurations with the surface area enhancements. For example, an extrusion of a thin plate with axially extending grooves imparted during the extrusion may have appropriate lengths cut for rectangular shapes or trimmed for circular shapes as desired. Additionally, plates or sheets of material may be heat pressed or vacuum molded to provide the enhanced surface area such as a latticed surface structure to the plate or sheet.

FIGS. 5-9 illustrate embodiments where the grooves on opposite sides of the form are offset from one another. This can provide maximum depth of the grooves providing maximum surface area. FIGS. 11-13 illustrate other configurations, and other configurations such as sinusoidal, sawtooth, or dovetail configurations are also contemplated as means of providing the corrugation or lattice work.

FIGS. 5A, 24A, and 25A illustrate known getter blocks or plates or sheets that may be formed into embodiments of the invention offering enhanced performance of the prior art forms. The preform 60 of FIG. 24A may be machined into the getter 62 with lattice structure 66 on each of the two major faces 68, 69. The preform 70 of FIG. 25A may be vacuum formed, for example, into the configuration of FIG. 25B. Alternatively the corrugated getter 74 of FIG. 25B may be extruded from a die with the corresponding shape.

FIGS. 14-16 and 22, 24B illustrate a configuration with bi-directional grooves to further enhance the surface area. Another alternative is holes which may be advantageous in thicker forms. Various features such as grooves, holes, undulations may be combined to provide optimal surface area structures and generally increase the exposed surface area to volume of getter material.

All of the features disclosed in this specification (including the references incorporated by reference, including any accompanying claims, abstract and drawings), and/or all of the steps of any method or process so disclosed, may be combined in any combination, except combinations where at least some of such features and/or steps are mutually exclusive.

Each feature disclosed in this specification (including references incorporated by reference, any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment (s). The invention extends to any novel one, or any novel combination, of the features disclosed in this specification (including any incorporated by reference references, any accompanying claims, abstract and drawings), or to any novel one, or any novel combination, of the steps of any method or process so disclosed The above references in all sections of this application are herein incorporated by references in their entirety for all purposes.

Although specific examples have been illustrated and described herein, it will be appreciated by those of ordinary skill in the art that any arrangement calculated to achieve the same purpose could be substituted for the specific examples shown. This application is intended to cover adaptations or variations of the present subject matter. Therefore, it is intended that the invention be defined by the attached claims and their legal equivalents, as well as the following illustrative aspects. The above described aspects embodiments of the invention are merely descriptive of its principles and are not to be considered limiting. Further modifications of the invention herein disclosed will occur to those skilled in the respective arts and all such modifications are deemed to be within the scope of the invention.

1. A substrate container comprising:
a containment defining an interior and comprising structure for holding a substrate, the substrate one of a reticle, a semiconductor wafer, and a flat panel, the substrate susceptible to air born contaminants;
a getter comprising a polymer and a molecular sieve material, the getter having an surface with a repeating pattern of a plurality of grooves in each of two major opposing surfaces providing surface area enhancements.

2. The substrate container of claim 1 wherein the plurality of grooves are parallel to one another and each groove extends at least 40% through a thickness defined by the two major opposing surfaces.

3. (canceled)

4. The substrate container of claim 1 in combination with the one of a reticle, a wafer, and a flat panel.

5. The substrate container of claim 1 wherein the getter has a plate shape and the plurality of the grooves are part of a lattice structure with recesses defined by the lattice structure extending at least 50% through a thickness defined by the opposing major surfaces.

6. The substrate container of claim 1 wherein the getter has a block shape having a length l, a width w, and a thickness t, and the getter has a surface area of at least 1.5 times (2(l×w)+2(l×t)+2(w×t)).

7. The substrate container of claim 6 wherein the getter has a surface area of at least 2.0 times 2(l×w)+2(l×t)+2(w×t)).

8. The substrate container of claim 1 wherein the getter has a circular plate shape having a diameter r, and a thickness t, and the getter has a surface area of at least 1.5 times (2πr²+(t2πr)).

9. The substrate container of claim 1 wherein the getter has a circular plate shape having a diameter r, and a thickness t, and the getter has a surface area of at least 2.0 times (2πr²+(t2πr)).

10. The substrate container of claim 1, wherein the container is a first container and further comprising a second container thereby providing a dual containment substrate container and wherein the dual containment substrate container is configured for holding a reticle.

11. The substrate container of claim 10 wherein the second container is enclosed in the first container and the getter is positioned and secured exterior the second container.

12. The substrate container of claim 1, wherein the getter is positioned in a getter pocket in the container and is secured therein with each of two major sides spaced from container walls.

13. The substrate container of claim 1 wherein the container comprises polycarbonate.

14. The substrate container of claim 10 wherein the container has container walls formed substantially of polycarbonate.

15. (canceled)

16. The substrate container of claim 1, wherein the substrate container comprises a footprint with an area and the area of a footprint of the getter is at least 30% of the area of the footprint of the substrate container.

17-19. (canceled)

20. The substrate container of claim 4 wherein the substrate has a major surface with a surface area and the getter has a major surface with a surface area at least 50% of the surface area of the substrate.

21-30. (canceled)

31. A substrate container comprising:
a containment defining an interior and comprising structure of holding a substrate, the substrate susceptible to air born contaminants;
a getter comprising a polymer and a molecular sieve material, the getter having an surface with a repeating pattern of recesses or apertures across a major surface thereby providing a surface area enhancement, the getter beings solid, homogeneous, and unitary.

32. The substrate container of claim 31 wherein the repeating pattern of recesses or apertures is on two major surfaces and extends at least 40% through a thickness defined by the two major opposing surfaces.

33. The substrate container of claim 31 wherein the substrate container is configured to contain one of a reticle and a wafer.

34. The substrate container of claim 33 in combination with the one of a reticle, a wafer, and a flat panel.

35-49. (canceled)

50. A front opening wafer container comprising a container portion with a front opening for receiving wafers, a door for sealingly closing the front opening, and a getter configured as a plate positioned in the container portion, the getter formed of a unitary polymer matrix with absorbent material held in the polymer matrix, the getter having a face with a repeating recess structure extending thereacross.
